(19) United States
(12) Patent Application Publication
(10) Pub. No.: US 2007/0032006 A1
(43) Pub. Date: Feb. 8, 2007

(54) FABRICATION METHOD OF FLASH MEMORY

(76) Inventors: Szu-Hsien Liu, Hsinchu County (TW); Houng-Chi Wei, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,769

(22) Filed: Jan. 11, 2006

(30) Foreign Application Priority Data
Aug. 8, 2005 (TW) 94126670

(51) Int. Cl. H01L 21/8234; H01L 21/336

(52) U.S. Cl. 438/197

(57) ABSTRACT

A fabrication method of a flash memory is provided. The substrate having a cell region and a peripheral circuitry region is provided. A patterned dielectric layer and a patterned conductive layer are formed on the substrate, and isolation structures are formed in the substrate. An inter gate dielectric layer and a poly layer are formed sequentially over the substrate. The poly layer and the inter gate dielectric in peripheral circuitry region are removed. After forming a second conductive layer and a mask layer over substrate, memory cells are formed in the cell region and a gate structure is formed in the peripheral circuitry region. A conductive plug is formed above the gate structure for electrically connecting the second conductive layer. Since the inter gate dielectric layer in the peripheral circuitry region is removed, the fabrication of the conductive plug can be simpler and the process window thereof can be improved.

### CROSS-REFERENCE TO RELATED APPLICATION

This application claims the priority benefit of Taiwan application serial no. 94126670, filed on Aug. 8, 2005. All disclosure of the Taiwan application is incorporated herein by reference.

### BACKGROUND OF THE INVENTION

1. Field of Invention

The present invention relates to a fabrication method of a semiconductor device, particularly, to a fabrication method of a flash memory.

2. Description of Related Art

Memories are semiconductor devices used for storing information or data. As the microprocessors in computers become more powerful to be compatible with growingly massive amount of programs and calculations executed by the software, the capacities of the memories need to boost up. The developments of memories moves toward fabricating large-storage and low-cost memories to meet the requirements in semiconductor manufacture.

Flash memory devices have been widely used as non-volatile memory devices in personal computers and electronic equipments because data can be read, stored and deleted repeatedly in the flash memory device and the stored data is remained even without power supply.

FIG. 1A illustrates a conventional flash memory. The flash memory is disposed on the P-substrate 100. The P-substrate 100 is divided into a cell region 102 and a peripheral circuitry region 104. The N-well 103, P-well 105, device isolation structure 106, tunneling oxide layer 108, conductive layer 110, conductive layer 112, composite inter gate dielectric layer 114, conductive layer 116, and cap layer 118 are formed in the cell region 102 of P-substrate 100. The P well 104, device isolation structure 106, composite inter gate dielectric layer 114, conductive layer 116, cap layer 118, high voltage gate oxide layer 120, the periphery gate 122, conductive plug 124, and conductive line 126 are formed in the peripheral circuitry region 104 of P-substrate 100 peripheral circuitry region.

In the peripheral circuitry region 104 of the flash memory as shown in FIG. 1A, the device isolation structure 106 is fabricated by the self-aligned shallow trench isolation (SASTI) process. The periphery gate 122 is composed of conductive layer 110 and conductive layer 112. In addition, the conductive layer 110, conductive layer 112, composite inter gate dielectric layer 114, conductive layer 116, and the cap layer 118 in the peripheral circuitry region 104 are formed along with the layers of the same reference numerals in the cell region 102, respectively. To electrically connect the conductive plug 124 to the periphery gate 122, a part of the inter gate dielectric layer 114, conductive layer 116, and cap layer 118 have to be removed to expose a part of the periphery gate 122 before fabricating the conductive plug 124. However, the size of the periphery gate 122 has to be large enough to be compatible with the process window of fabricating the conductive plug 124. In addition, there is high contact resistance between the periphery gate 122 and the conductive plug 124 because the material of the periphery gate 122 is doped polysilicon and the material of the conductive plug 124 is tungsten. Therefore, the conventional flash memory structure cannot meet the requirements of high integration and uniform electrical properties.

FIG. 1B is a diagram illustrating the peripheral circuitry region of another conventional flash memory. The peripheral circuitry region is formed on the substrate 1 30. The isolation structure 132, conductive layer 134, inter gate dielectric layer 136, conductive layer 138, cap layer 140, spacers 142, conductive plug 144, conductive line 146, and dielectric layer 148 are disposed over the substrate 130. The conductive layer 134, inter gate dielectric layer 136, conductive layer 138, and cap layer 140 form a gate structure.

For the flash memory as illustrated in FIG. 1B, it is difficult to satisfy the requirement of size reduction and suitable process window for the lithography process. Since the conductive plug 144 are used to electrically connect conductive layer 138 to conductive line 146 and to electrically connect conductive layer 134 and conductive layer 138 and two lithography processes are performed to the gate structure, the size of the gate structure has to be large enough to provide suitable process windows of two lithography and etching processes. Hence, the size of the gate structure can not be reduced and the integration of the memory may not be increased. Furthermore, with the limited gate structure size, the process window of the above-mentioned lithography and etching process for electrically connecting the conductive layer 134 with conductive layer 138 is very small.

### SUMMARY OF THE INVENTION

Accordingly, the present invention is directed to provide a fabrication method of a flash memory, to solve the problem caused by the increase of device integration.

According to another aspect of the present invention, a fabrication method of a flash memory is provided, to reduce the contact resistance between the conductive plug and the gate structure.

The present invention provides a fabrication method of a flash memory. A substrate having a cell region and a peripheral circuitry region is provided. Afterward, a patterned dielectric layer and a patterned first conductive layer are formed on the substrate, and the first conductive layer is located on the dielectric layer. Subsequently, a plurality of isolation structures is formed in the substrate. In addition, a plurality of strip-shaped second conductive layers is formed over the substrate in the cell region, and the third conductive layer is formed over the substrate in the peripheral circuitry region. The second conductive layers are located between the device isolation structures and are separated from each other. Additionally, an inter gate dielectric layer is formed over the substrate and a fourth conductive layer is formed on the inter gate dielectric layer. The fourth conductive layer and the inter gate dielectric layer in the peripheral circuitry region are removed and a fifth conductive layer is formed over the substrate. After a cap layer is formed on the fifth conductive layer, the cap layer, the fifth conductive layer, the fourth conductive layer, the inter gate dielectric layer, the second conductive layer, and the first conductive layer in the cell region are patterned to form a plurality of memory cells, and the cap layer, the fifth conductive layer, the fourth conductive layer, the third conductive layer, and the first conductive layer in the peripheral circuitry region are patterned to form a gate structure. A conductive line, for electrically connecting the fifth conductive layer, is formed over the gate structure in the peripheral circuitry region.

According to an embodiment of the present invention, the fabrication method of a flash memory further comprises forming a patterned mask layer on the first conductive layer. Through the patterns of the mask layer, the dielectric layer and the first conductive layer, the device isolation structures in the substrate are formed by removing a part of the exposed substrate to form a plurality of trenches in the substrate, filling an insulating material layer in the trenches, removing a part of the insulating material layer until the mask layer is exposed, and removing the mask layer.

According to an embodiment of the present invention, the material of the first conductive layer, the second conductive layer, the third conductive layer, and the fourth conductive layer can be, for example, doped polysilicon.

According to an exemplary embodiment of the present invention, the fifth conductive layer can be, for example, a polycide layer including a doped polysilicon layer and a tungsten silicide layer.

According to an exemplary embodiment of the present invention, the inter gate dielectric layer is, for example, an oxide-nitride-oxide (ONO) layer.

According to an exemplary embodiment of the present invention, the fabrication method further includes forming a conductive plug to electrically connect the conductive line and the fifth conductive layer.

According to an exemplary embodiment of the present invention, the fabrication method further includes forming a plurality of spacers on sidewalls of the memory cells and the gate structure.

According to an exemplary embodiment of the present invention, the steps of removing the fourth conductive layer and the inter gate dielectric layer in the peripheral circuitry region include forming a patterned photoresist layer over the substrate to cover the cell region and expose the peripheral circuitry region, removing the fourth conductive layer and the inter gate dielectric layer exposed by the patterned photoresist layer, and removing the patterned photoresist layer.

In the fabrication method provided by the present invention, no inter gate dielectric layer is formed in the gate structure in the peripheral circuitry region, and the fifth conductive layer, the third conductive layer and the first conductive layer in the gate structure are electrically connected. Therefore, only one lithography and etching process is needed to be performed for the gate structure using the fifth conductive layer as the etch-stop layer, to form the conductive plug and the conductive plug can electrically connect the gate structure to the external. For only one lithography etching process performed to the gate structure, the step of forming the conductive plug has a larger process window, and the size of the gate structure may be smaller. Moreover, since the material of the fifth conductive layer is polycide, the contact resistance between the fifth conductive layer and the metallic conductive plug may be reduced dramatically. In addition, since the fourth conductive layer provides protection to the inter gate dielectric layer, the above-mentioned steps of removing the patterned photoresist layer will not damage the inter gate dielectric layer in the cell region.

According to another aspect of the present invention, a fabrication method of a flash memory is provided. A substrate having a cell region and a peripheral circuitry region is provided. A plurality of device isolation structures is formed in the substrate. A first dielectric layer and a first conductive layer are formed between two adjacent device isolation structures in the cell region, and a second dielectric layer is formed between two adjacent device isolation structures in the peripheral circuitry region. A second conductive layer is formed over the substrate in the peripheral circuitry region. In addition, an inter gate dielectric layer is formed over the substrate and a third conductive layer is formed on the inter gate dielectric layer. Subsequently, the third conductive layer and the inter gate dielectric layer in the peripheral circuitry region are removed. A fourth conductive layer is formed over the substrate and a cap layer is formed on the fourth conductive layer. The cap layer, the fourth conductive layer, the third conductive layer, the inter gate dielectric layer, and the first conductive layer in the cell region are patterned to form a plurality of memory cells, and the cap layer, the fourth conductive layer, and the second conductive layer in the peripheral circuitry region are patterned to form a gate structure. Finally, a conductive line above the gate structure in the peripheral circuitry region is formed to electrically connect the fourth conductive layer.

According to an exemplary embodiment of the present invention, the material of the first conductive layer, the second conductive layer, and the third conductive layer can be, for example, doped polysilicon.

According to an exemplary embodiment of the present invention, the fourth conductive layer is, for example, a polycide layer including a doped polysilicon layer and a tungsten silicide layer.

According to an exemplary embodiment of the present invention, the inter gate dielectric layer is, for example, an oxide-nitride-oxide layer.

According to an exemplary embodiment of the present invention, the fabrication method further includes forming a conductive plug to electrically connect the conductive line and the fourth conductive layer.

According to an exemplary embodiment of the present invention, the fabrication method further includes forming a plurality of spacers on sidewalls of the memory cells and gate structure.

According to an exemplary embodiment of the present invention, the steps of removing the third conductive layer and the inter gate dielectric layer in the peripheral circuitry region include forming a patterned photoresist layer over the substrate to cover the cell region and expose the peripheral circuitry region, removing the third conductive layer and the inter gate dielectric layer exposed by the patterned photoresist layer, and then removing the patterned photoresist layer.

With the fabrication method provided by the present invention, no inter gate dielectric layer is formed in the gate structure in the peripheral circuitry region, and the fourth conductive layer is electrically connected to the second conductive layer in the gate structure. Accordingly, one lithography and etching process is performed to the gate structure using the fourth conductive layer as the etch-stop layer to form the conductive plug and the conductive plug can electrically connect the gate structure to the external. With only one lithography and etching process is performed for the gate structure, a larger process window is provide and the size of the gate structure may be smaller. Moreover, since the material of the fourth conductive layer is polycide, the contact resistance between the fourth conductive layer and the metallic conductive plug can be reduced dramatically. On the other hand, since the third conductive layer is protective to the inter gate dielectric layer, the above-mentioned step of removing the patterned photoresist layer will not damage the inter gate dielectric layer in the memory cell region.

In order to make the aforementioned and other objectives, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A illustrates a conventional flash memory.

FIG. 1B illustrates another conventional flash memory.

FIG. 2A to 2D are cross-sectional display views illustrating the fabrication process steps of a flash memory according to an embodiment of the present invention.

FIG. 2E is a cross-sectional display view of FIG. 2D along line I-I′ and line II-II′.

FIG. 2F illustrates the step subsequent to fabrication process step of FIG. 2E.

FIG. 3A to 3C are cross-sectional display views illustrating the fabrication process steps of a flash memory according to another embodiment of the present invention.

FIG. 3D is a cross-sectional display view of FIG. 3C along line II-II′ and line IV-IV′.

FIG. 3E illustrates the step subsequent to the fabrication process step of FIG. 3D.

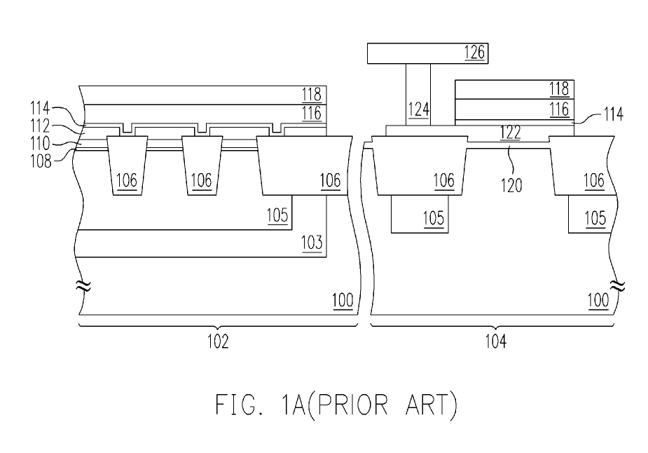

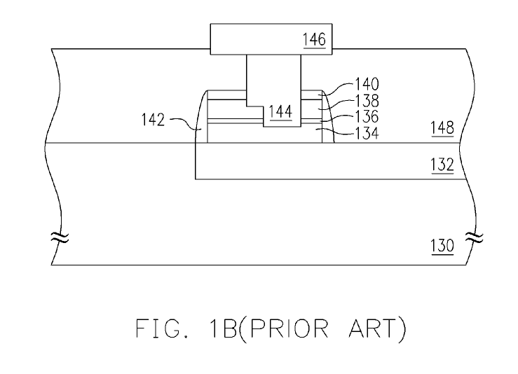

### DESCRIPTION OF EMBODIMENTS

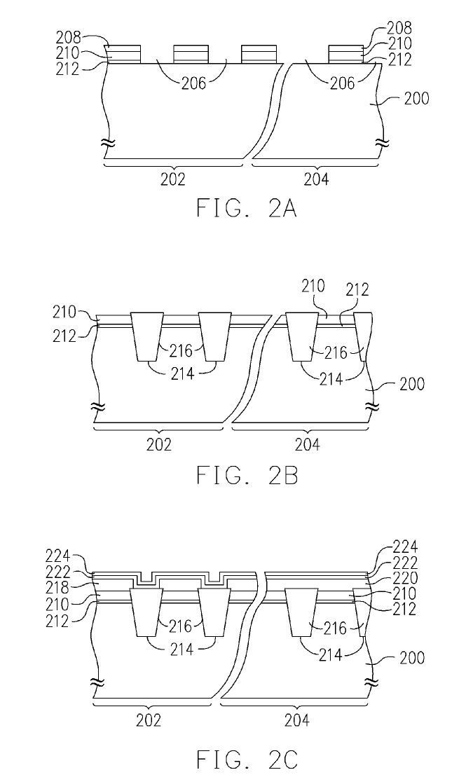

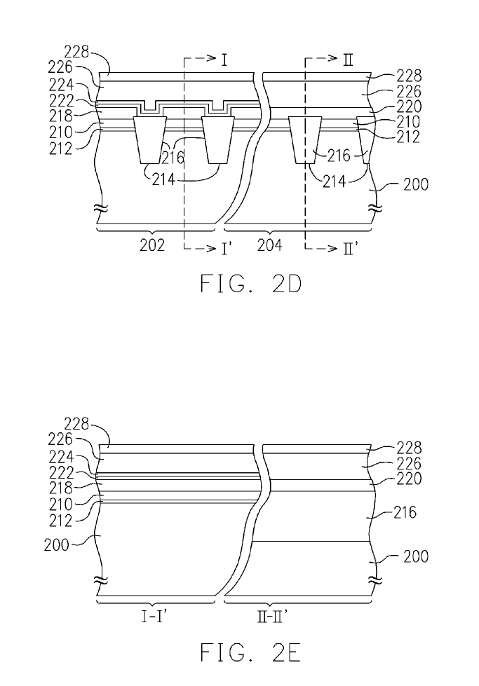

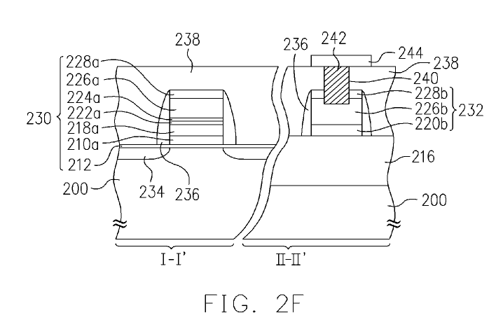

FIG. 2A to 2F are cross-sectional display views illustrating the fabrication process steps of a flash memory according to an embodiment of the present invention wherein FIG. 2E and 2F illustrates the same step in the fabrication flow and FIG. 2E is a cross-sectional display view of FIG. 2D along the sectional lines I-I′ and II-II′. FIG. 2F illustrates the step subsequent to the fabrication process step of FIG. 2E.

Referring to FIG. 2A, the substrate 200 is provided. The substrate 200 comprises a memory cell region 202 and the peripheral circuitry region 204. A dielectric material layer (not shown), a conductive material layer (not shown), and a mask layer (not shown) are formed sequentially on the substrate 200. The material of the dielectric material layer is, for example, silicon oxide, and the formation method thereof is, for example, thermal oxidation. The material of the conductive material layer is, for example, doped polysilicon, and the formation method thereof is, for example, chemical vapor deposition (CVD), and in-situ doping using the dopant gas of phosphine (PH₃). The material of the mask layer is, for example, silicon nitride, and the formation method thereof is, for example, CVD. Subsequently, the mask layer, the conductive material layer, and the dielectric material layer are patterned to form the mask layer 208, the conductive layer 210, and the dielectric layer 212. A plurality of openings 206 exposing the substrate 200 is formed in the mask layer 208, the conductive layer 210, and the dielectric layer 212. The dielectric layer 212 may be used as a tunneling dielectric layer. In addition, the layers are patterned through, for example, the lithography and etching processes.

In addition, referring to FIG. 2B, the substrate 200 that is exposed by the openings 206 is removed to form a plurality of trenches 214 in the substrate 200. The trenches 214 are formed by, for example, dry etching. Additionally, an insulating material layer (not shown herein) is formed over the substrate 200, filling up the trench 214. The material of the insulating material is, for example, silicon oxide. The formation method of the insulating material layer is, for example, CVD. Subsequently, a part of the insulating material layer is removed until the surface of the mask layer 208 is exposed. The method of removing part of the insulating material layer can be, for example, chemical mechanical polishing (CMP) using the mask layer 208 as the polish-stop layer. Afterwards, the mask layer 208 is removed. The method of removing the mask layer 208 is, for example, (plasma) dry etching. Given steps discussed above, a plurality of device isolation structures 216 is formed in the substrate 200, and a dielectric layer 212 and a conductive layer 210 are disposed between two adjacent device isolation structures 216.

In addition, referring to FIG. 2C, a plurality of strip-shaped conductive layers 218 is formed in the memory cell region 202 and over the substrate 200, and a conductive layer 220 is formed in the peripheral circuitry region 204 and over the substrate 200. The conductive layers 218 are disposed between the device isolation structures and are separated from one another. The material of the conductive layer 220 and the conductive layers 218 can be, for example, doped polysilicon, and the formation method is, for example, performing a CVD using silane (SiH₄) and phosphine (PH₃) as reactants to form a conductive material layer and removing a part of the conductive material layer with lithography and etching processes. In addition, an inter gate dielectric layer 222 is formed over the substrate 200. For example, the inter gate dielectric layer 222 is a composite dielectric layer. The composite dielectric layer can be, for example, an oxide-nitride-oxide layer and silicon oxide is formed by, for example, thermal oxidation and CVD and silicon nitride is formed by, for example, CVD. To protect the inter gate dielectric layer 222, a conductive layer 224 is formed on the inter gate dielectric layer 222. The material of the conductive layer 224 is, for example, doped polysilicon, and the formation method of the doped polysilicon is identical to the aforementioned formation method of doped polysilicon.

Additionally, referring to FIG. 2D, a patterned photoresist layer (not shown herein) is formed over the substrate 200 to cover the memory cell region 202 but expose the peripheral circuitry region 204. The conductive layer 224 and the inter gate dielectric layer 222 in the peripheral circuitry region 204 that are exposed by the patterned photoresist layer are removed. The method for removing the conductive layer 224 and the inter gate dielectric layer 222 includes, for example, performing a dry etching process to the conductive layer 224 and the inter gate dielectric layer 222 and removing the patterned photoresist layer. The method of removing the patterned photoresist layer includes, for example, performing an ashing process using dry oxygen plasma with a solution of H₂SO₄ and H₂O₂. It is noted that the etching process will not damage the inter gate dielectric layer 222 in the memory cell region 202 because the conductive layer 224 is disposed thereon. Additionally, a conductive layer 226 is formed over the substrate 200 and the conductive layer 226 is, for example, a polycide layer including a doped polysilicon layer and a tungsten silicide layer. The formation method of the doped polysilicon layer is identical to the aforementioned formation method of doped polysilicon. The formation method of the tungsten silicide layer is, for example, CVD with tungsten hexafluoride (WF₆) and silane (SiH₄) as reactants. In addition, a cap layer 228 is formed on the conductive layer 226 and the material of the cap layer 228 is, for example, silicon nitride.

Additionally, for the convenience of descriptions, it is necessary to describe the present process from a view different from that of FIG. 2A to 2D. Please refer to FIG. 2E, a cross-sectional view along the sectional lines: I-I′ and II-II′ in FIG. 2D, wherein area I-I′ is a cross-sectional view of section line I-I′ in FIG. 2D and area II-II′ is a cross-sectional view of sectional line II-II′ in FIG. 2D.

Referring to FIG. 2F, the cap layer 228, conductive layer 226, conductive layer 224, inter gate dielectric layer 222, conductive layer 218, and conductive layer 210 of the structure of area I-I′ are patterned and the memory cell(s) 230, which is composed of the cap layer 228a, conductive layer 226a, conductive layer 224a, inter gate dielectric layer 222a, conductive layer 218a, conductive layer 210a, and dielectric layer 212, is formed. The cap layer 228, conductive layer 226, and conductive layer 220 of area II-II′ are patterned to form a gate structure 232 which is composed of the cap layer 228b, conductive layer 226b, and conductive layer 220b.

Additionally, a source/drain region 234 is formed in the exposed part of the substrate 200 of area I-I′, by, for example, ion implantation. A layer of silicon oxide or silicon nitride (not shown) is then formed over the substrate 200 by, for example, CVD, and an anisotropic etching process is performed to form a plurality of spacers 236 on the sidewalls of memory cell 230 and the sidewalls of gate structure 232. An inter layer dielectric layer 238 is formed over the substrate 200 and the material of the inter layer dielectric layer 238 is, for example, boro-phospho-silicate glass (BPSG).

Additionally, in area II-II′, the cap layer 228b and the inter layer dielectric layer 238 covering the cap layer 228 are patterned to form a contact window opening 240 and to expose at least the conductive layer 226b. A conductive plug 242 is then formed in the contact window opening 240. The formation method of the conductive plug 242 is, for example, sputtering a barrier layer of titanium/titanium nitride over the surface of the substrate 200, and a tungsten layer on the barrier layer by CVD. Subsequently, an etching back process is performed to remove the tungsten outside of the contact window opening 240. Additionally, a conductive line 244 is formed over the substrate 200 to electrically connect the conductive plug 242. The conductive line 244 can be formed, for example, during the metallization process of aluminum. The conductive layer 226b is electrically connected to the conductive line 244 through the conductive plug 242, and electrically connected to the external through the conductive line 244.

It is noted that the fabrication method of a flash memory provided by the present invention has at least the following advantages:

Since the inter gate dielectric layer in the peripheral circuitry region has been removed in advance, the conductive layers of the gate structure in the peripheral circuitry region are electrically connected to one another. Accordingly, the formed conductive plug needs not to provide the function of electrically connecting various conductive layers. Therefore, the formation of the conductive plug is simpler and provides larger process window and the size of the gate structure may be designed to be smaller to increase the integration of the memory device.

Since the conductive layer 224, which has the functionality of protecting the inter gate dielectric layer 222 of the memory cell region 202 is formed, the inter gate dielectric layer 222 will not be damaged in the subsequent process.

Since the material of the conductive layer 226b in the gate structure 232 is polycide, the contact resistance between the conductive layer 226b and the conductive plug 242 is very low, beneficial for the electrical control of the gate structure 232.

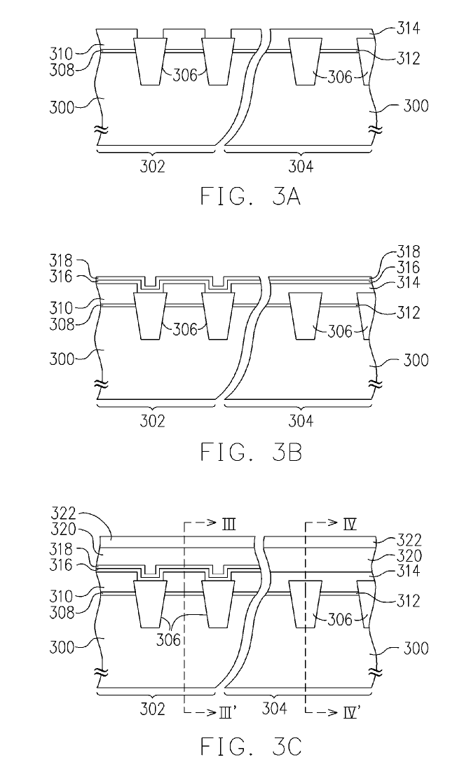

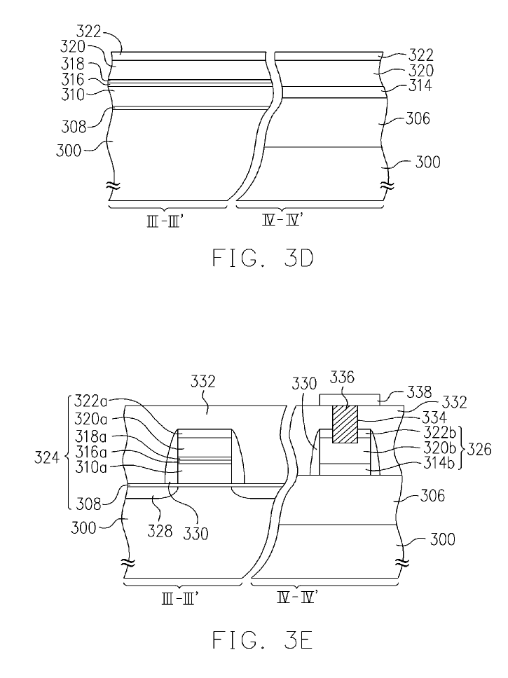

FIG. 3A to 3E are cross-sectional display views of fabrication process steps of a flash memory according another embodiment of the present invention, FIG. 3C and 3D illustrate the same step in the fabrication flow. FIG. 3D is a cross-sectional display view along sectional line I-I′ and line II-II′ in FIG. 3C. FIG. 3E illustrates the step subsequent to the fabrication process step of FIG. 3D.

Referring to FIG. 3A, first, the substrate 300, which includes a memory cell region 302 and a peripheral circuitry region 304, is provided. A plurality of device isolation structures 306 is formed in the substrate 300. A dielectric layer 308 and a conductive layer 310 disposed on the dielectric layer 308 are formed between two adjacent device isolation structure 302s in the memory cell region 302. A dielectric layer 312 is formed between two adjacent device isolation structure 306s in the peripheral circuitry region 304, and a conductive layer 314 is formed on the substrate 300 in the peripheral circuitry region 304.

Referring to FIG. 3B, an inter gate dielectric layer 316 is formed over the substrate 300 and the inter gate dielectric layer 316 is, for example, a composite dielectric layer. The composite dielectric layer can be, for example, an oxide-nitride-oxide layer and silicon oxide is formed by, for example, thermal oxidation and CVD and silicon nitride is formed by, for example, CVD. To protect the inter gate dielectric layer 316, a conductive layer 318 is formed on the inter gate dielectric layer 316, the material of the conductive layer 318 is, for example, doped polysilicon by CVD using silane (SiH₄) and phosphine (PH₃) as reactants

Referring to FIG. 3C, the conductive layer 318 and the inter gate dielectric layer 316 of the peripheral circuitry region 304 are removed. The removal method includes forming a patterned photoresist layer (not shown herein) over the substrate 300 to cover the memory cell region 302 and to expose the peripheral circuitry region 304 first and then removing the conductive layer 318 and the inter gate dielectric layer 316 exposed by the patterned photoresist layer. The removal method includes, for example, performing a dry etching process to the conductive layer 318 and the inter gate dielectric layer 316 and then removing the patterned photoresist layer. The method of removing the patterned photoresist layer includes, for example, performing an ashing process to the substrate 300. It is noted that the ashing process will not damage the inter gate dielectric layer 316 of the memory cell region 302 because the conductive layer 318 is disposed thereon. Afterwards, a conductive layer 320 is formed over the substrate 300 and the conductive layer 320 is, for example, a polycide layer including a doped polysilicon layer and a tungsten silicide layer. The formation method of the doped polysilicon layer may be identical to the aforementioned formation method of the doped polysilicon. The formation method of the tungsten silicide layer is, for example, CVD using tungsten hexafluoride (WF₆) and silane (SiH₄) as reactants. Additionally, a cap layer 322 is formed on the conductive layer 320 and the material of the cap layer 322 is, for example, silicon nitride.

Referring to FIG. 3D, area II-II′ is a cross-sectional view of sectional line II-II′ in FIG. 3C and area IV-IV′ is a cross-sectional view of sectional line IV-IV′ in FIG. 3C. Referring to FIG. 3E, the cap layer 322, conductive layer 320, conductive layer 318, inter gate dielectric layer 316, and conductive layer 310 of area II-II′ are patterned to form the memory cell(s) 324, which is composed of the cap layer 322a, conductive layer 320a, conductive layer 318a, inter gate dielectric layer 316a, conductive layer 310a, and dielectric layer 308. The cap layer 322, conductive layer 320, and conductive layer 314 of area IV-IV′ are patterned to form the gate structure 326, which is composed of the cap layer 322b, conductive layer 320b, and conductive layer 314b.

Referring to FIG. 3E, the source/drain region 328 is formed in the exposed part of the substrate 300 in area III-III′ by, for example, ion implantation. A layer of silicon oxide or silicon nitride (not shown herein) is formed over the substrate 300 by, for example, CVD and a plurality of spacers 330 are formed on the sidewalls of memory cell 324 and the sidewalls of gate structure 326 by anisotropic etching.

Referring to FIG. 3E, an inter layer dielectric layer 332 is formed over the substrate 300 and the material of the inter layer dielectric layer 332 is, for example, boro-phospho-slilcate glass (BPSG). In area IV-IV′, the cap layer 322b and the inter layer dielectric layer 332 covering the cap layer 322b are patterned to form a contact window opening 334, which exposes at least the conductive layer 320b. Subsequently, a conductive plug 336 is formed in the contact window opening 334. The formation method of the conductive plug 336 includes, for example, sputtering a barrier layer of titanium/titanium nitride over the surface of the substrate 300, depositing a tungsten layer on the barrier layer by CVD and etching back the tungsten outside of the contact window opening 334. In addition, the conductive line 338 is formed over the substrate 300 to electrically connect the conductive plug 336. The conductive line 338 can be formed during, for example, the metallization process of aluminum. The conductive layer 320b is electrically connected to the conductive line 338 through the conductive plug 336 and then electrically connected to the external through the conductive line 338.

It is noted that the fabrication method of a flash memory provided by the present invention has at least the following advantages:

Since the inter gate dielectric layer of the peripheral circuitry region has been removed in advance, the various conductive layers of the gate structure of the peripheral circuitry region are electrically connected to one another. The formed conductive plug needs not to have the function of electrically connecting various conductive layers. Therefore, the formation of the conductive plug is simpler and provides larger process window and the size of the gate structure may be designed to be smaller to increase the integration of the memory device.

Since the conductive layer 318 which has the functionality of protecting the inter gate dielectric layer 316 of the memory cell region 302 is formed, the inter gate dielectric layer 316 will not be damaged in the subsequent process.

Since the material of the conductive layer 320b in the gate structure 326 is polycide, the contact resistance between the conductive layer 320b and the conductive plug 336 is very low, beneficial for the electrical control of the gate structure 326.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A fabrication method of a flash memory, comprising:
providing a substrate having a memory cell region and a peripheral circuitry region;
forming a patterned dielectric layer and a patterned first conductive layer on the substrate, wherein the patterned first conductive layer is disposed on the patterned dielectric layer;
forming a plurality of device isolation structures in the substrate using the patterned dielectric layer and the patterned first conductive layer as a mask;
forming a plurality of strip-shaped second conductive layers over the substrate in the memory cell region, and forming a third conductive layer over the substrate in the peripheral circuitry region, wherein the second conductive layers are disposed between the device isolation structures and the second conductive layers are separated from one another;
forming an inter gate dielectric layer over the substrate;
forming a fourth conductive layer on the inter gate dielectric layer;
removing the fourth conductive layer and the inter gate dielectric layer in the peripheral circuitry region;
forming a fifth conductive layer over the substrate;
forming a cap layer on the fifth conductive layer;
patterning the cap layer, the fifth conductive layer, the fourth conductive layer, the inter gate dielectric layer, the second conductive layer, and the first conductive layer in the memory cell region to form a plurality of memory cells, and patterning the cap layer, the fifth conductive layer, the third conductive layer, and the first conductive layer in the peripheral circuitry region to form a gate structure; and
forming a conductive line above the gate structure in the peripheral circuitry region, for electrically connecting with the fifth conductive layer.

2. The fabrication method as claimed in claim 1, further comprises forming a patterned mask layer on the patterned first conductive layer, wherein the step of forming a plurality of device isolation structures in the substrate comprises:
removing a part of the substrate exposed by the patterned dielectric layer, the patterned first conductive layer, and the patterned mask layer to form a plurality of trenches in the substrate;
forming an insulating material layer over the substrate to fill the trenches;
removing a part of the insulating material layer until the mask layer is exposed; and
removing the mask layer.

3. The fabrication method as claimed in claim 1, wherein a material of the patterned first conductive layer includes doped polysilicon.

4. The fabrication method as claimed in claim 1, wherein a material of the second conductive layer and the third conductive layer includes doped polysilicon.

5. The fabrication method as claimed in claim 1, wherein a material of the fourth conductive layer includes doped polysilicon.

6. The fabrication method as claimed in claim 1, wherein a material of the fifth conductive layer includes polycide.

7. The fabrication method as claimed in claim 6, wherein polycide includes doped polysilicon and tungsten silicide.

8. The fabrication method as claimed in claim 1, wherein the inter gate dielectric layer includes an oxide-nitride-oxide layer.

9. The fabrication method as claimed in claim 1, further comprising a conductive plug electrically connecting the conductive line and the fifth conductive layer.

10. The fabrication method as claimed in claim 1, further comprising forming a plurality of spacers on sidewalls of the memory cells and sidewalls of the gate structure.

11. The fabrication method as claimed in claim 1, wherein the step of removing the fourth conductive layer and the inter gate dielectric layer in the peripheral circuitry region comprises:
forming a patterned photoresist layer over the substrate to cover the memory cell region and expose the peripheral circuitry region;
removing the fourth conductive layer and the inter gate dielectric layer exposed by the patterned photoresist layer; and
removing the patterned photoresist layer.

12. A fabrication method of a flash memory, comprising:
providing a substrate having a memory cell region and a peripheral circuitry region, wherein the substrate comprises a plurality of device isolation structures in the substrate, a first dielectric layer and a first conductive layer between two adjacent device isolation structures in the memory cell region, a second dielectric layer between two adjacent device isolation structures in the peripheral circuitry region, and a second conductive layer disposed on the substrate in the peripheral circuitry region;
forming an inter gate dielectric layer over the substrate;
forming a third conductive layer on the inter gate dielectric layer;
removing the third conductive layer and the inter gate dielectric layer in the peripheral circuitry region;
forming a fourth conductive layer over the substrate;
forming a cap layer on the fourth conductive layer;
patterning the cap layer, the fourth conductive layer, the third conductive layer, the inter gate dielectric layer, and the first conductive layer in the memory cell region to form a plurality of cells, and patterning the cap layer, the fourth conductive layer, and the second conductive layer in the peripheral circuitry region to form a gate structure; and
forming a conductive line above the gate structure in the peripheral circuitry region to electrically connect the fourth conductive layer.

13. The fabrication method as claimed in claim 12, wherein a material of the first conductive layer and the second conductive layer includes doped polysilicon.

14. The fabrication method as claimed in claim 12, wherein a material of the third conductive layer includes doped polysilicon.

15. The fabrication method as claimed in claim 12, wherein a material of the fourth conductive layer includes polycide.

16. The fabrication method as claimed in claim 15, wherein polycide includes doped polysilicon and tungsten silicide.

17. The fabrication method as claimed in claim 12, wherein the inter gate dielectric layer includes an oxide-nitride-oxide layer.

18. The fabrication method as claimed in claim 12, further comprising forming a conductive plug to electrically connect the conductive line and the fourth conductive layer.

19. The fabrication method as claimed in claim 12, further comprising forming a plurality of spacers on sidewalls of the cells and sidewalls of the gate structure.

20. The fabrication method as claimed in claim 12, wherein the step of removing the third conductive layer and the inter gate dielectric layer in the peripheral circuitry region comprises:
forming a patterned photoresist layer on the substrate to cover the cell region and to expose the peripheral circuitry region;
removing the third conductive layer and the inter gate dielectric layer exposed by the patterned photoresist layer; and
removing the patterned photoresist layer.
